(19) United States
(12) Patent Application Publication
(10) Pub. No.: US 2016/0211405 A1
(43) Pub. Date: Jul. 21, 2016

(54) METHOD OF MANUFACTURING SEMICONDUCTOR DEVICE

(71) Applicant: CANON KABUSHIKI KAISHA, Tokyo (JP)

(72) Inventor: Hideomi Kumano, Tokyo (JP)

(21) Appl. No.: 14/967,650

(22) Filed: Dec. 14, 2015

(30) Foreign Application Priority Data
Jan. 21, 2015 (JP) 2015-009238

(51) Int. Cl. H01L 31/18

(52) U.S. Cl. CPC H01L 31/1876

(57) ABSTRACT

A method includes the steps of: forming a plurality of recessed portions in an insulating film formed above a wafer including a first region and a second region outside the first region such that the recessed portions are formed above both the first region and the second region; forming a conductive film on the insulating film such that the plurality of recessed portions are filled with the conductive film; removing the conductive film above the second region while leaving the conductive film above the first region; and removing part of the conductive film remaining above the first region outside the plurality of recessed portions, wherein an area proportion of the recessed portions each having a projected area of 10 μm² or smaller on the wafer among the plurality of recessed portions is higher in the second region than in the first region.

### BACKGROUND OF THE INVENTION

1. Field of the Invention

The present invention relates to a method of manufacturing a semiconductor device.

2. Description of the Related Art

Among recent manufacturing processes for semiconductor devices, a widely-used wiring formation process is what is termed as a damascene process. The damascene process involves: forming recessed portions (trenches) or recessed portions including via holes; then filling a metal material containing copper into the recessed portions by plating or the like; and performing planarization by removing the metal material outside the recessed portions by chemical mechanical polishing (CMP).

In the process of filling the copper into the via holes and the recessed portions, a copper film is also deposited on part of an outer peripheral portion of the front surface of a semiconductor wafer such as a silicon wafer, and part of the side surface and the back surface of the semiconductor wafer. If the wafer having the copper film bared on the outer peripheral portion, the side surface, or the back surface thereof is conveyed to equipment used in the next process, the copper in the copper film bared on the wafer adheres to a wafer stage, a wafer carrier, a conveyor and the like, and thereby contaminates the equipment. When the copper adhered to the surfaces of the equipment adheres to the wafer, the adhered copper is diffused into the wafer, and changes characteristics in an element region. To avoid this, after the deposition of the copper film, the unnecessary copper film on the outer peripheral portion, the side surface, and the back surface of the wafer needs to be removed before the wafer is conveyed to the next process. This removal of the unnecessary copper film uses, for example, nitric acid or concentrated sulfuric acid (Japanese Patent Application Laid-Open No. 2003-203912).

Meanwhile, providing dummy shots on an outer peripheral portion of a wafer has been proposed in order to make the processed dimensions and processed shapes uniform over the entire surface of the wafer (Japanese Patent Application Laid-Open No. H06-20903). In addition, in order to prevent a fine pattern from coming off an edge portion of a wafer, forming a dummy pattern on a peripheral region of the wafer has been also proposed, the dummy pattern having a minimum dimension that is at least larger than a minimum dimension of the pattern present in an inner region of the wafer (Japanese Patent Application Laid-Open No. H05-304072).

However, around the boundary of a region where the unnecessary copper film is removed, there is a section where the copper film is only partly removed and still partly remains. In such a section where the copper film partly remains, a modified layer is formed on a surface of the remaining copper film due to a remover liquid used to remove the copper film. The modified layer thus formed acts as a factor in a delamination of upper layer films originating from the modified layer, and thus results in a decrease in the yield of products. Moreover, if the copper film is bared due to the delamination, the manufacturing equipment may be contaminated by the copper, and all the products manufactured by the manufacturing equipment may be adversely affected by the contamination.

### SUMMARY OF THE INVENTION

An object of the present invention is to provide a method of manufacturing a semiconductor device which is capable of improving the yield by suppressing delamination around the boundary of a region where an unnecessary conductive film is removed, and inhibiting contamination by a conductive film material due to the baring of the conductive film.

According to one aspect of the present invention, a method of manufacturing a semiconductor device includes the steps of: forming a plurality of recessed portions in an insulating film formed above a wafer including a first region and a second region outside the first region such that the recessed portions are formed above both the first region and the second region; forming a conductive film on the insulating film such that the plurality of recessed portions are filled with the conductive film; removing the conductive film above the second region while leaving the conductive film above the first region; and removing part of the conductive film remaining above the first region outside the plurality of recessed portions, wherein an area proportion of the recessed portions each having a projected area of 10 μm2 or smaller on the wafer among the plurality of recessed portions is higher in the second region than in the first region.

According to this aspect of the present invention, it is possible to improve the yield by suppressing delamination around the boundary of a region where an unnecessary conductive film is removed, and to inhibit contamination by a conductive film material due to the baring of the conductive film.

Further features of the present invention will become apparent from the following description of exemplary embodiments with reference to the attached drawings.

### BRIEF DESCRIPTION OF THE DRAWINGS

FIGS. 1A and 1B are schematic plan views illustrating an exposure region and others in a semiconductor wafer.

FIG. 2 is a schematic plan view illustrating a mask pattern to be used in a method of manufacturing a semiconductor device according to a reference mode.

FIGS. 3A, 3B, 3C, 4A, 4B, 4C, 5A, 5B and 6 are schematic cross sectional views illustrating the method of manufacturing a semiconductor device according to the reference mode.

FIG. 7 is a schematic cross sectional view for explaining delamination originating from a modified layer formed on the surface of a copper film.

FIGS. 8A and 8B are schematic plan views illustrating mask patterns to be used in a method of manufacturing a semiconductor device according to a first embodiment of the present invention.

FIGS. 9A, 9B, 9C, 10A, 10B, 10C, 11A, 11B and 12 are schematic cross sectional views illustrating the method of manufacturing a semiconductor device according to the first embodiment of the present invention.

FIG. 13 is a schematic plan view illustrating a configuration of a semiconductor device according to a second embodiment of the present invention.

### DESCRIPTION OF THE EMBODIMENTS

Preferred embodiments of the present invention will now be described in detail in accordance with the accompanying drawings.

(Reference Mode)

In general, in a damascene process of forming a copper wiring, recessed portions such as trenches are provided in an insulating film. Then, copper is filled into the recessed portions by plating or the like, and the unnecessary copper film on an outer peripheral portion, the side surface and the back surface of a wafer is removed by a remover liquid made of nitric acid or the like. In the outer peripheral portion of the wafer, around the boundary of the region where the unnecessary copper film is removed, there are sections among which how much the copper film is removed varies. More specifically, around the boundary, there are a section where the copper film is completely removed, a section where the copper film is only partly removed and still remains partly, and a section where the copper film is not removed.

In the damascene process, planarization is performed after the aforementioned removal. In the planarization, the conductive film such as the copper film deposited outside the recessed portions is removed by CMP. Next, a barrier insulating film for preventing diffusion of copper is formed on the insulating film in which the recessed portions are filled with the conductive film such as the copper film. Thereafter, films such as an insulating film serving as an inter-layer film (inter-layer insulating film) and a passivation film prone to produce relatively high film stress are sequentially formed on the barrier insulating film. After that, a hydrogen sintering process in which the wafer is thermally treated in an atmosphere containing a hydrogen gas is performed in order to reduce the interface states at an interface between the silicon and the silicon oxide film. Thereby, dangling bonds of the silicon are terminated by the hydrogen.

It should be noted that there is a section where the copper film is only partly removed and still partly remains around the boundary of the region where the aforementioned unnecessary copper film is removed. In such a section where the copper film partly remains, a modified layer is formed on the surface of the remaining copper film by the remover liquid used to remove the copper film. The modified layer thus formed deteriorates adhesion between the barrier insulating film formed on top of the copper film, and its underlying layer.

Meanwhile, the passivation film prone to produce relatively high film stress is formed on top of the inter-layer insulating film. In addition, thermal stress is applied to the wafer due to the thermal treatment such as the hydrogen sintering process or the like. If the stress such as the film stress and thermal stress is applied to the wafer in which the adhesion between the barrier insulating film and the underlying layer is deteriorated due to the copper modified layer, the stress may cause a problem of the occurrence of delamination of the upper layer films originating from the modified layer. Moreover, if a recessed portion having large dimensions is arranged in the outer peripheral portion of the wafer, presumably the modified layer may have a large area and resultantly cause the delamination more easily.

When the delamination occurs as described above, particles are generated. This results in a decrease in the yield of products. Moreover, if the copper film is bared due to the delamination, the copper may contaminate the manufacturing equipment, and may adversely affect all the products manufactured by the manufacturing equipment. For this reason, it is necessary to suppress the delamination due to the copper modified layer.

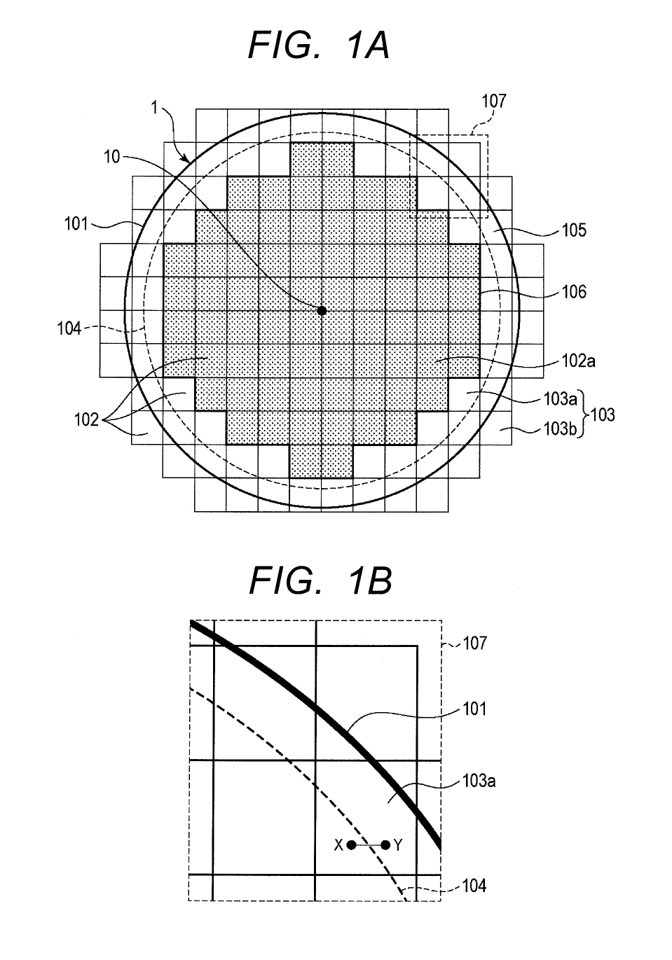

Here, prior to description of embodiments of the present invention, a case where wiring layers are formed by the aforementioned damascene process and where delamination occurs will be described in more details as a reference mode by using FIGS. 1A and 1B, FIGS. 3A to 3C, FIGS. 4A to 4C, FIGS. 5A and 5B, FIG. 6, and FIG. 7.

FIG. 1A is a schematic plan view illustrating an exposure region, a removal region where a conductive film forming the wiring layer is to be removed, and the like in a semiconductor wafer (also referred to as a wafer, below) 1 in which semiconductor devices are to be fabricated.

FIG. 1A depicts the wafer 1 with a principal surface as an element formation surface of the wafer 1 viewed from right above the center 10 of the wafer 1. An outer periphery 101 is an outer periphery of the wafer 1, i.e., an outer edge of the principal surface of the wafer 1. In the following description, with respect to a certain point or region on the principal surface of the wafer 1, “inside” refers to a side closer to the center 10 of the wafer 1, and “outside” refers to a side closer to the outer periphery 101 of the wafer 1. In addition, FIG. 1A depicts a grid for explaining the exposure region. As described later, an exposure to be performed on the exposure region depicted with the grid is an exposure in a process of forming a resist pattern to be used in etching to form recessed portions in a certain layer.

Here, multiple semiconductor devices (semiconductor chips) are fabricated from a single semiconductor wafer, in general. In FIG. 1A, multiple chip segments 102 corresponding to chips to be fabricated are arranged on a single wafer 1. The multiple chip segments 102 on the wafer 1 are defined by scribe lines. In the process of manufacturing semiconductor devices, the chip segments 102 are cut along the scribe lines and thereby divided into effective chips and ineffective chips. Each effective chip is a rectangular chip, and is used as a semiconductor device. The ineffective chips include rectangular chips and non-rectangular chips. A non-rectangular chip, for example, may have a shape containing a part of the outer periphery 101.

The wafer 1 includes an effective region 106 where semiconductor devices can be formed, and an ineffective region 105 which is other than the effective region 106 and in which no semiconductor devices can be formed. An entire region between the outer periphery 101 and the effective region 106 can be the ineffective region 105. In FIG. 1A, the effective region 106 is hatched, and the ineffective region 105 is not hatched. On the wafer 1, a region excluding an outer peripheral portion of the wafer and having an outer edge 104 is a region where a conductive film for forming a conductive pattern constituting a wiring layer is to be formed. Among the multiple chip segments 102, the chip segments 102 included in the effective region 106 are effective chip segments 102a. All the multiple effective chip segments 102a are arranged inside the outer edge 104 of the region where the conductive film is to be formed. Among the multiple chip segments 102, the chip segments 102 included in the ineffective region 105 are ineffective chip segments 103. More specifically, in the ineffective region 105, the chip segments 102 arranged to cross the outer edge 104 are ineffective chip segments 103a, and the chip segments 102 arranged outside the outer edge 104 are ineffective chip segments 103b. To put it differently, only when the entirety of one effective chip segment 102a is arranged inside the outer edge 104, the effective chip segment 102a is usable to form a single semiconductor device. In the wafer 1 illustrated in FIG. 1A, the number of finished semiconductor devices is 72, and these semiconductor devices are obtained respectively from 72 effective chip segments 102a included in the effective region 106 where semiconductor devices can be formed.

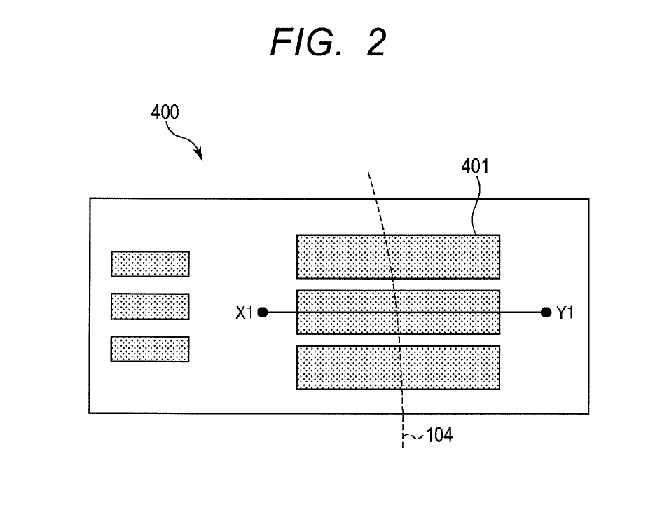

FIG. 1B is a schematic plan view illustrating an enlarged view of a noticed region 107 surrounded by a dashed line in FIG. 1A. FIG. 2 is a schematic plan view illustrating a mask pattern for forming recessed portions for the wiring layer on an X-Y line in FIG. 1B. The mask pattern 400 illustrated in FIG. 2 is formed in a reticle to be used in an exposure of a photoresist film for forming a resist pattern in the ineffective chip segments 103. FIG. 2 depicts an X1-Y1 line as a line corresponding to the X-Y line in FIG. 1B. As illustrated in FIG. 2, the mask pattern 400 for forming the recessed portions for the wiring layer on the X-Y line includes patterns 401 corresponding to the shapes of the recessed portions. In a resist pattern obtained by exposure using the mask pattern 400, patterns corresponding to the patterns 401 are opening patterns in which the insulating film to be dry-etched is exposed. The mask pattern 400 used for the first ineffective chip segments 103a is the same as the mask pattern used for the effective chip segments 102a in the effective region 106 where semiconductor devices can be formed. In addition, the mask pattern used for the second ineffective chip segments 103b is also the same as the mask pattern used for the effective chip segments 102a.

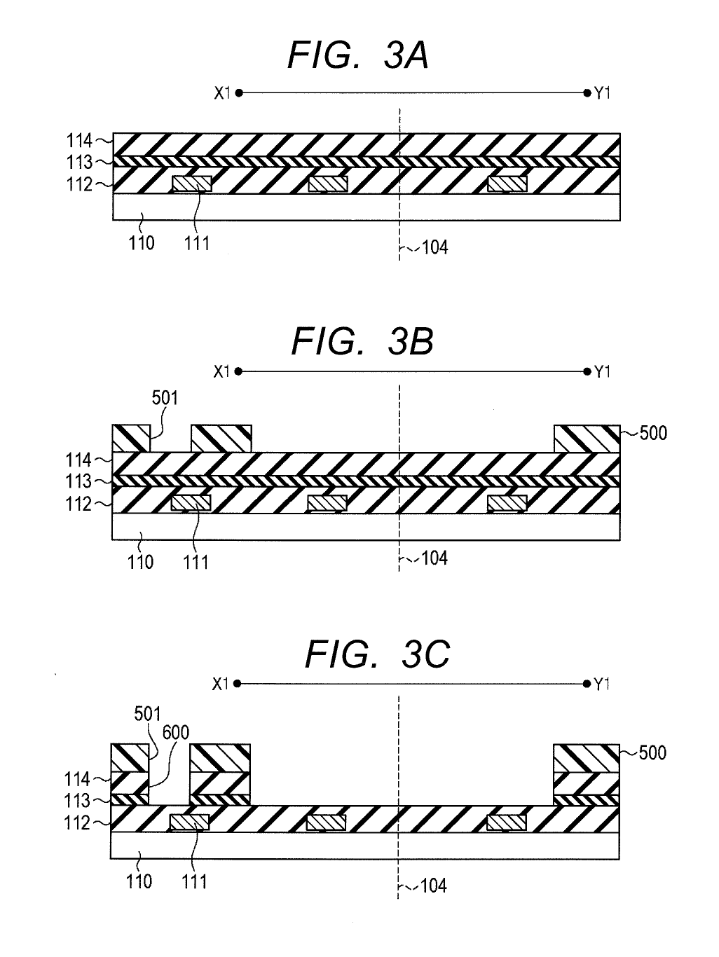

Hereinafter, a method of manufacturing a semiconductor device including wiring layers on the X1-Y1 line illustrated in FIG. 2 is described by using FIGS. 3A to 3C, FIGS. 4A to 4C, FIGS. 5A and 5B, FIG. 6, and FIG. 7. FIGS. 3A to 3C, FIGS. 4A to 4C, FIGS. 5A and 5B, and FIG. 6 are schematic cross sectional views illustrating the method of manufacturing a semiconductor device including wiring layers on the X1-Y1 line illustrated in FIG. 2. FIG. 7 is a schematic cross sectional view for explaining delamination originating from a modified layer formed on the surface of a copper film.

First of all, various kinds of semiconductor elements such as transistors, bipolar transistors, resistance elements, and capacitance elements are formed on a semiconductor wafer (semiconductor substrate) 110 such as a silicon wafer made of single crystal silicon. Here, FIGS. 3A to 6 illustrate a case where transistors including gate electrodes 111 are formed as semiconductor elements. Usual semiconductor manufacturing processes can be used to form the semiconductor elements.

Next, an inter-layer insulating film 112 is formed by chemical vapor deposition (CVD), for example, such that the inter-layer insulating film 112 can cover the semiconductor elements formed on the semiconductor wafer 110. The inter-layer insulating film 112 may be a silicon oxide film (SiO film), for example. The surface of the inter-layer insulating film 112 may be flattened by CMP.

Subsequently, a stopper insulating film 113 is deposited on the inter-layer insulating film 112 by CVD, for example. The stopper insulating film 113 functions as an etching stopper, and may be a silicon carbide film (SiC film), a silicon nitride film (SiN film), a silicon carbon nitride film (SiCN film), or the like, for example.

Thereafter, as illustrated in FIG. 3A, an inter-layer insulating film 114 for forming wirings is deposited on the stopper insulating film 113 by CVD, for example. The inter-layer insulating film 114 may be a SiO film, for example.

Then, the inter-layer insulating film 114 is coated with a photoresist film 500. Subsequently, the photoresist film 500 is exposed to light, and thereby patterns for forming recessed portions are formed in the photoresist film 500 as illustrated in FIG. 3B. The photoresist film 500 having the patterns formed therein includes an opening 501 in a region where each recessed portion is to be formed. In this process, in the effective chip segments 102a, and the ineffective chip segments 103a, 103b illustrated in FIG. 1A, the patterns for forming recessed portions are formed in the photoresist film 500 by using the same mask pattern. Specifically, the mask pattern 400 illustrated in FIG. 2 is used for the effective chip segments 102a and the ineffective chip segments 103a, 103b, as described above. This stabilizes the processed dimensions, processed shapes and flatness over the entire surface of the semiconductor wafer 110.

Next, the inter-layer insulating film 114 and the stopper insulating film 113 are sequentially dry-etched by using the photoresist film 500 as a mask. Thereby, multiple recessed portions 600 being trenches for forming wirings are formed in the inter-layer insulating film 114 and the stopper insulating film 113, as illustrated in FIG. 3C.

Then, the photoresist film 500 is removed by asking, for example.

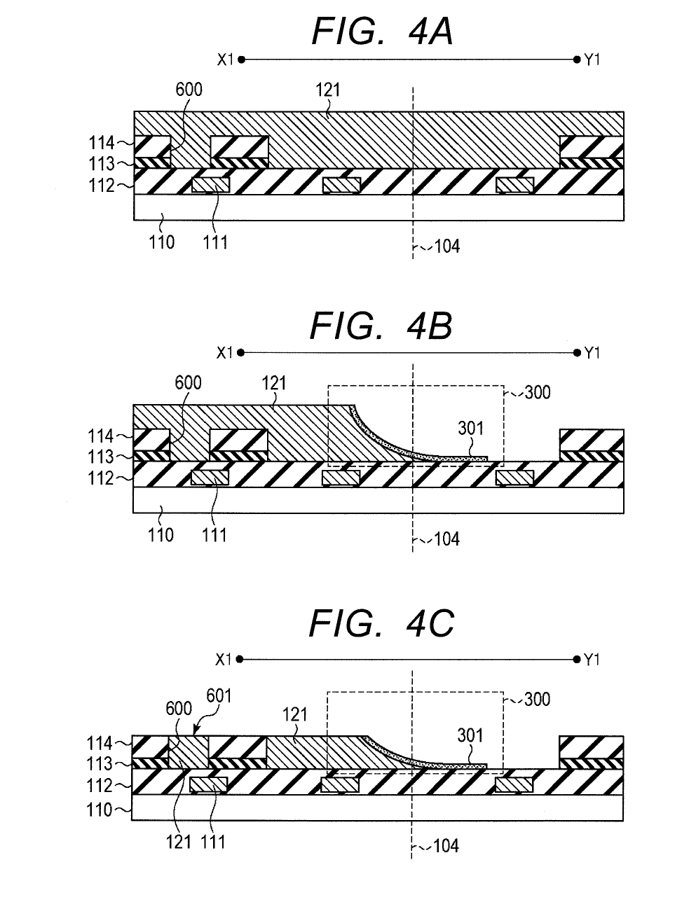

Next, a barrier metal film (not illustrated) such as a titanium film (Ti film) or a titanium nitride film (TiN film) is formed on the inter-layer insulating film 114 including the multiple recessed portions 600 therein by sputtering, for example. Subsequently, a seed film (not illustrated) made of a copper film (Cu film) is formed on the barrier metal film by sputtering, for example. Then, as illustrated in FIG. 4A, a copper film 121 as a conductive film is formed on the seed film by electroplating, for example, such that the multiple recessed portions 600 are filled with the copper film 121.

After that, as illustrated in FIG. 4B, the copper film 121 deposited as an unnecessary conductive film on the outer peripheral portion, the side surface, and the back surface of the semiconductor wafer 110 is removed while the copper film 121 is left on a region including the outer edge 104. Thus, using the outer edge 104 as a boundary on the principal surface of the semiconductor wafer 110, the copper film 121 is left on the region inside the outer edge 104, while the copper film 121 is removed from the region outside the outer edge 104. This removal uses, as a remover liquid, an aqueous solution of nitric acid, concentrated sulfuric acid, sulfuric acid/hydrogen peroxide mixture, or the like, for example. In addition, the removal method is not particularly limited as long as the method can remove the unnecessary copper film 121 from the outer peripheral portion, the side surface, and the back surface of the semiconductor wafer 110 by using a remover liquid.

In this process, a section 300 where the copper film 121 is only partly removed and still partly remains is formed around the boundary of the region where the process of removing the unnecessary copper film 121 is performed, that is, around the outer edge 104. The surface of the copper film 121 in the section 300 where the copper film 121 partly remains is modified by the remover liquid used in the aforementioned removal. As a result, a copper modified layer 301 is formed on the surface of the copper film 121 in the section 300.

Subsequently, as illustrated in FIG. 4C, the copper film 121, the seed film and the barrier metal film on the inter-layer insulating film 114 are polished by using CMP. This process selectively removes part of the copper film 121, the seed film and the barrier metal film on the inter-layer insulating film 114 outside the multiple recessed portions 600. Thus, a wiring layer 601 having the copper films 121 filled inside the recessed portions 600 is formed. In the section 300 where the copper film 121 partly remains, steps are generated due to the removal of the copper film 121, and therefore slurry used for polishing in the CMP is likely to be stuck on the steps (this phenomenon is referred to as slurry sticking).

Next, a barrier insulating film 115 having a function to prevent diffusion of copper is deposited by CVD, for example, on the inter-layer insulating film 114 having the wiring layer 601 embedded therein. The barrier insulating film 115 may be, for example, a SiN film, a SiCN film, a SiC film, or the like.

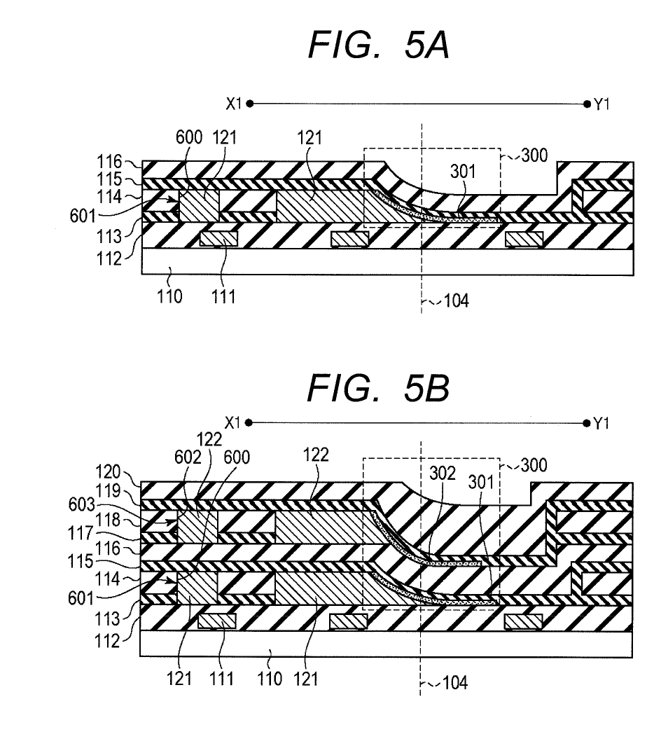

Subsequently, as illustrated in FIG. 5A, an inter-layer insulating film 116 is deposited on the barrier insulating film 115 by CVD, for example. The inter-layer insulating film 116 may be, for example, a SiO film, a fluorinated silicate glass (FSG) film, a silicon oxide carbide film (SiOC film), or the like.

In the section 300 where the copper film 121 partly remains, the modified layer 301 is present on the surface of the copper film 121, as described above. The modified layer 301 deteriorates the adhesion between barrier insulating film 115 on top of the modified layer 301, and its underlying layer. In addition, in the section 300, the slurry sticking is likely to occur in the polishing process by CMP. For these reasons, the modified layer 301 tends to be an origin for delamination in which the upper layers on the modified layer 301 are delaminated.

Thereafter, the wiring formation processes described by using FIGS. 3B to 5A are repeated. In this way, a multilayer wiring including multiple wiring layers is formed as illustrated in FIG. 5B. In an example illustrated in FIG. 5B, a stopper insulating film 117 and an inter-layer insulating film 118 are formed on the inter-layer insulating film 116, and a wiring layer 603 having copper films 122 filled in recessed portions 602 formed in the stopper insulating film 117 and the inter-layer insulating film 118 is formed. A modified layer 302 similar to the modified layer 301 is formed on the surface of the copper film 122 remaining in the section 300. Then, a barrier insulating film 119 and an inter-layer insulating film 120 are sequentially deposited on the inter-layer insulating film 118 having the wiring layer 603 embedded therein.

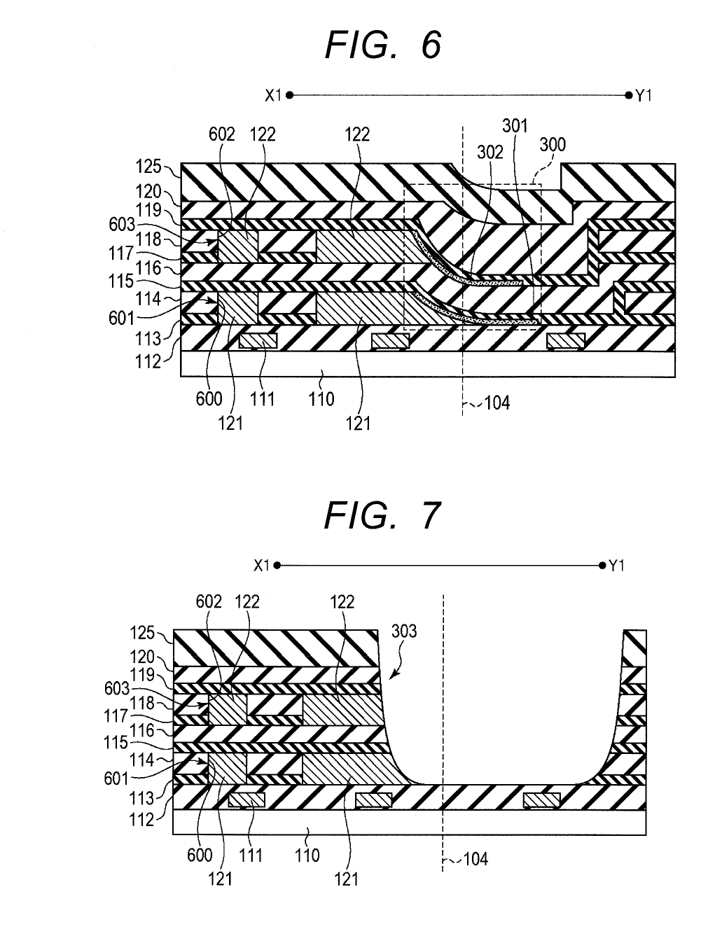

Next, as illustrated in FIG. 6, a passivation film 125 is formed on the inter-layer insulating film 120 by CVD, for example. The passivation film 125 may be, for example, a SiN film.

The passivation film 125 is prone to produce relatively high film stress. In addition, in a process after the formation of the passivation film 125, the semiconductor wafer 110 having the multilayer wiring formed therein is thermally treated in an atmosphere containing a hydrogen gas in order to reduce the interface states at an interface between the silicon and the silicon oxide film. Thereby, the dangling bonds of the silicon are terminated with the hydrogen. The thermal treatment in this process is a thermal treatment at about 400° C., for example. Such a thermal treatment applies thermal stress to the semiconductor wafer 110 including the inter-layer insulating films, the wiring layers and the like.

If stress such as the film stress due to the passivation film 125 and the thermal stress due to the thermal treatment is applied to the semiconductor wafer 110 including the inter-layer insulating films and the like, the stress may cause aforementioned delamination originating from any of the modified layers formed on the surfaces of the copper films. FIG. 7 is a schematic cross sectional view illustrating delamination originating from the modified layer 301 as an example of delamination. As illustrated in FIG. 7, a delamination section 303 is generated in which delamination of the upper layer films on the modified layer 301 occurs originating from the modified layer 301. In the delamination section 303, the barrier insulating film 115, the inter-layer insulating film 116, the stopper insulating film 117, the inter-layer insulating film 118, the barrier insulating film 119, the inter-layer insulating film 120, and the passivation film 125 located on and above the modified layer 301 are delaminated. Here, similar delamination originating from the modified layer 302 is also likely to occur, although FIG. 7 illustrates the example of the delamination originating from the modified layer 301.

When the delamination occurs as described above, particles are generated. As a result, the yield of products is lowered. Moreover, the copper film may be bared due to the delamination, and the copper of the bared copper film may contaminate the manufacturing equipment. This case is a serious problem, because all the products manufactured using the manufacturing equipment may be adversely affected.

A method of manufacturing a semiconductor device according to the present invention is intended to improve the yield by suppressing delamination around the boundary of a region where a foregoing unnecessary conductive film such as a copper film is removed, and to inhibit contamination by a conductive film material due to the baring of the conductive film. Hereinafter, the embodiments of the present invention will be described in detail.

### First Embodiment

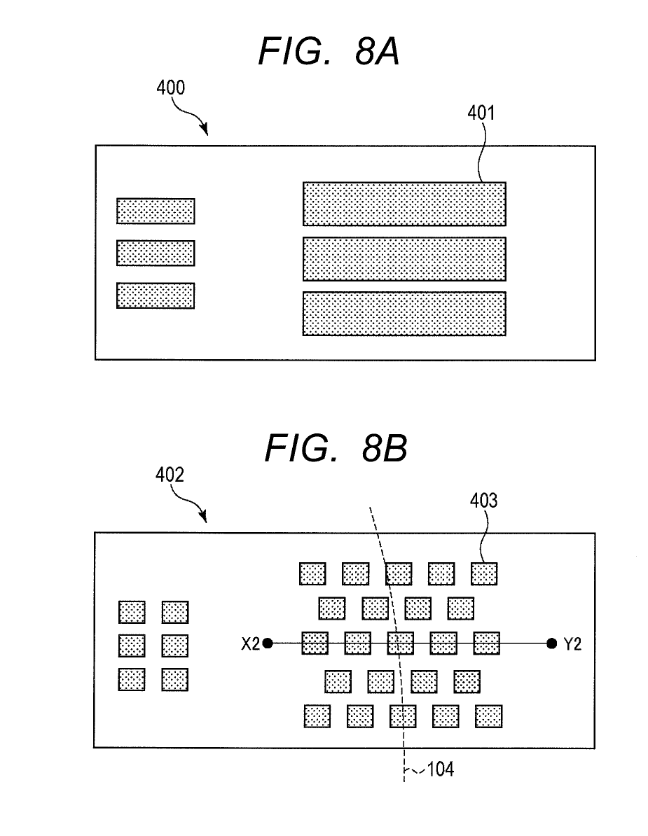

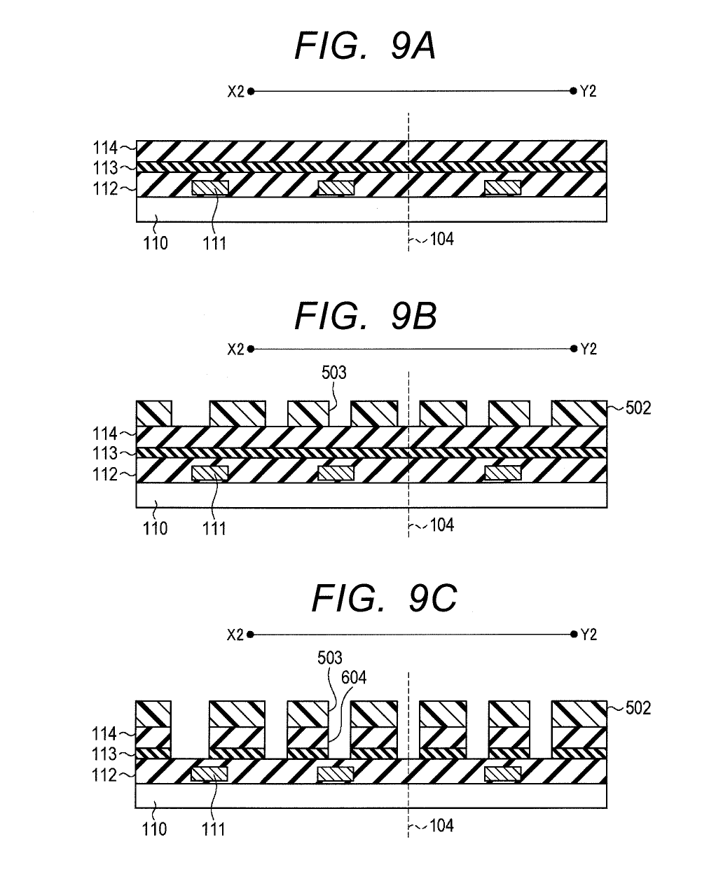

Hereinafter, a method of manufacturing a semiconductor device according to a first embodiment of the present invention will be described by using FIGS. 8A and 8B, FIGS. 9A to 9C, FIGS. 10A to 10C, FIGS. 11A and 11B, and FIG. 12. FIGS. 8A and 8B are schematic plan views for explaining mask patterns used in the method of manufacturing a semiconductor device according to the present embodiment. FIGS. 9A to 9C, FIGS. 10A to 10C, FIGS. 11A and 11B, and FIG. 12 are schematic cross sectional views illustrating the method of manufacturing a semiconductor device according to the present embodiment. Note that, constituent elements similar to those in the reference mode will be assigned with the same reference numerals, and the explanation thereof will be omitted or simplified. In addition, the drawings used for the explanation of the reference mode will be also referred to as needed.

The method of manufacturing a semiconductor device according to the present embodiment is characterized in that an exposure of ineffective chip segments 103a, 103b uses a mask pattern different from the mask pattern used in the exposure of the effective chip segments 102a in the aforementioned effective region 106 where semiconductor devices can be formed.

FIGS. 8A and 8B illustrate the mask patterns for forming recessed portions in the present embodiment. Mask patterns 400, 402 illustrated in FIGS. 8A and 8B are formed in reticles to be used in an exposure of a negative-type photoresist film for forming a resist pattern.

In the present embodiment, in the exposure for forming recessed portions, the effective chip segments 102a are exposed to light by using the mask pattern 400 illustrated in FIG. 8A, for example. The mask pattern 400 illustrated in FIG. 8A is similar to the mask pattern 400 illustrated in FIG. 2, and includes patterns 401 corresponding to the shapes of the recessed portions.

On the other hand, likewise in the exposure for forming recessed portions, the ineffective chip segments 103a, 103b are exposed to light by using the mask pattern 402 illustrated in FIG. 8B. The mask pattern 402 illustrated in FIG. 8B includes multiple island patterns 403. In a resist pattern obtained with the mask pattern 402, portions corresponding to the island patterns 403 are shaded from light in the exposure, remain able to dissolve in a developer, and after development, form openings from which the insulating film is to be dry-etched. A similar resist pattern may also be formed by exposing a positive-type photoresist film to light by use of a mask pattern reverse to the mask pattern 402. Incidentally, in the exposure, light having passed through the patterns formed in the reticle is kept unchanged or reduced in magnification, and is projected to the photoresist film. In this example, the light having passed through the patterns is reduced at a ¼ magnification. In addition, a mask pattern for multiple chips is formed in one reticle, and multiple chip segments are simultaneously exposed to light by one exposure shot.

FIG. 8B illustrates an example in which the multiple island patterns 403 each having a rectangular planar shape are arranged in a staggered array. It should be noted that the planar shape and the array of the island patterns 403 are not limited to those illustrated in FIG. 8B. The planar shape of the island pattern 403 may be a circular shape or oval shape, for example. Then, the multiple island patterns 403 may be arranged in a square grid array, for example.

Moreover, each island pattern 403 is designed such that the opening of the island pattern 403 can form a recessed portion having a projected area of 10 μm² or smaller. It should be noted that the projected area described herein is a projected area of a recessed portion on the wafer, the recessed portion formed by using as a mask a photoresist film to which the pattern is transferred by an exposure. More specifically, a virtual pattern obtained by reversing an island pattern corresponding to each island pattern 403 in a resist pattern formed by an exposure using the mask pattern 402 has a projected area of 10 μm² or smaller on the wafer.

As for a recessed portion formed corresponding to each island pattern 403 and having a projected area of 10 μm² or smaller, a dimension of the recessed portion in a first direction along the wafer 110 is preferably 1 to 1000 times as large as a dimension of the recessed portion in a second direction along the wafer 110 and orthogonal to the first direction. Moreover, the dimension of the recessed portion, having a projected area of 10 μm² or smaller, in the first direction along the wafer 110 is more preferably to 10 times as large as the dimension of the recessed portion in the second direction along the wafer 110 and orthogonal to the first direction. For example, the shape of the recessed portion formed corresponding to the island pattern 403 may be a square having a side of 3.1 μm or smaller, or a circle having a radius of 1.7 μm or smaller. It is desirable that the maximum width of the recessed portion thus formed be equal to or smaller than the maximum width of the recessed portions formed in the effective region 106 by using the mask pattern 400 illustrated in FIG. 8A. Note that, the “width” mentioned above is a dimension of a short side of the recessed portion, if the recessed portion has long and short sides. The maximum width of the recessed portions formed in the ineffective region 105 by the exposure using the mask pattern 402 is desirably equal to or smaller than the maximum width of the recessed portions obtained by the exposure using the mask pattern 400. The maximum width of the recessed portions obtained by the exposure using the mask pattern 402 can be set as needed, but specifically may be 0.1 μm to 10 μm, for example. When the maximum width in the resist pattern for the ineffective chip segments 103a, 103b is set relatively small, the area of the aforementioned modified layer can be made small.

The mask pattern 400 illustrated in FIG. 8A may include island patterns each corresponding to a recessed portion having an area of 10 μm² or smaller in terms of the projected area, as similar to the island pattern 403. In this case, an area proportion of the island patterns corresponding to recessed portions each having an area of 10 μm² or smaller in terms of the projected area is different between the mask pattern 400 illustrated in FIG. 8A and the mask pattern 402 illustrated in FIG. 8B.

Specifically, the area proportion of recessed portions each having a projected area of 10 μm² or smaller and formed in the ineffective chip segments 103a, 103b is higher than the area proportion of recessed portions each having a projected area of 10 μm² or smaller and formed in the effective chip segments 102a. Here, the area proportion of the recessed portions formed in the ineffective chip segments 103a, 103b denotes a proportion (percentage) of a total sum of the projected areas of the recessed portions to a total area of the ineffective region 105 in which the ineffective chip segments 103a, 103b are arranged. The area proportion of the recessed portions formed in the effective chip segments 102a denotes a proportion (percentage) of a total sum of the projected areas of the recessed portions to a total area of the effective region 106 in which all the effective chip segments 102a are arranged.

By use of the resist pattern obtained by the exposure using the aforementioned mask patterns 400, 402, the area proportion of the recessed portions each having a projected area of 10 μm² or smaller on the wafer among all the multiple recessed portions is higher in the ineffective chip segments 103a, 103b than in the effective chip segments 102a. The area proportion mentioned herein denotes a proportion (percentage) of a total sum of the projected areas on the wafer of recessed portions formed corresponding to the island patterns in all the ineffective chip segments or all the effective chip segments with respect to the total area of all the ineffective chip segments or all the effective chip segments. In this way, it is preferable that the area proportion of the recessed portions formed corresponding to the island patterns in the resist pattern in the ineffective chip segments 103a, 103b be set relatively high. This can inhibit the aforementioned modified layer from being formed with a large area, and thereby can suppress delamination originating from the modified layer.

Here, the area proportion of the recessed portions each having a projected area of 10 μm² or smaller on the wafer in the ineffective chip segments 103a, 103b may be set as needed, but specifically may be 35% or more, for example. Meanwhile, since a certain space needs to be secured between recessed portions, the area proportion of the recessed portions each having a projected area of 10 μm² or smaller on the wafer is less than 100%, and typically may be 70% or less. In this way, the area proportion of the recessed portions each having a projected area of 10 μm² or smaller on the wafer in the ineffective chip segments 103a, 103b may be set to be equal to or more than 35%, but less than 100%, for example.

Here, the mask pattern 402 may include only the island patterns 403 corresponding to the recessed portions each having an area of 10 μm² or smaller in terms of the projected area. In this case, only the recessed portions each having a projected area of 10 μm² or smaller on the wafer are formed in the ineffective chip segments 103a, 103b. When recessed portions with a small area are only formed as described above, it is possible to more surely suppress delamination originating from the modified layer.

In addition, each of the mask patterns 400, 402 may include a pattern over 10 μm² which is an island pattern corresponding to a recessed portion having an area over 10 μm² in terms of the projected area. In this case, it is desirable that the area proportion of patterns over 10 μm² be different between the two mask patterns 400, 402.

Specifically, it is desirable that the area proportion of recessed portions formed in the effective chip segments 102a and each having a projected area over 10 μm² be higher than the area proportion of recessed portions formed in the ineffective chip segments 103a, 103b and each having a projected area over 10 μm². Here, the area proportion of recessed portions formed in the effective chip segments 102a is a proportion (percentage) of a total sum of the projected areas of the recessed portions to the total area of the effective region 106 where all the effective chip segments 102a are arranged. The area proportion of recessed portions formed in the ineffective chip segments 103a, 103b is a proportion (percentage) of a total sum of the projected areas of the recessed portions to the total area of the ineffective region 105 where the ineffective chip segments 103a, 103b are arranged.

By use of the resist pattern obtained by the exposure using the aforementioned mask patterns 400, 402, the area proportion of recessed portions each having a projected area over 10 μm² on the wafer among all the multiple recessed portions is higher in the effective chip segments 102a than in the ineffective chip segments 103a, 103b. The area proportion mentioned herein denotes a proportion (percentage) of a total sum of the projected areas on the wafer of recessed portions formed corresponding to the island patterns concerned in all the ineffective chip segments or all the effective chip segments with respect to the total area of all the ineffective chip segments or all the effective chip segments.

As described above, in the present embodiment, the mask pattern 402 including the relatively small island patterns 403 corresponding to recessed portions each having a projected area of 10 μm² or smaller as illustrated in FIG. 8B is used for the ineffective chip segments 103a, 103b. Thus, according to the present embodiment, the areas of the modified layers 301, 302 formed due to the removal of the unnecessary copper films can be made small, and thereby delamination originating from any of the modified layers 301, 302 can be suppressed.

Hereinafter, the method of manufacturing a semiconductor device using the foregoing mask patterns according to the present embodiment is further described by using FIGS. 9A to 9C, FIGS. 10A to 10C, FIGS. 11A and 11B, and FIG. 12. Here, FIG. 8B depicts an X2-Y2 line as a line corresponding to the X-Y line in FIG. 1B. The schematic cross sectional views illustrated in FIGS. 9A to 9C, FIGS. 10A to 10C, FIGS. 11A and 11B, and FIG. 12 illustrate the method of manufacturing a semiconductor device including the wiring layers on the X2-Y2 line.

First of all, various kinds of semiconductor elements such as transistors, bipolar transistors, resistance elements, and capacitance elements are formed on a semiconductor wafer (semiconductor substrate) 110 such as a silicon wafer made of single crystal silicon, as in the reference mode. Here, FIGS. 9A to 12 illustrate a case where transistors including gate electrodes 111 are formed as semiconductor elements.

Next, as illustrated in FIG. 9A, an inter-layer insulating film 112, a stopper insulating film 113, and an inter-layer insulating film 114 for forming wirings are deposited as in the reference mode.

Subsequently, the inter-layer insulating film 114 is coated with a photoresist film 502. Then, the photoresist film 502 is exposed to light, and thereby patterns for forming recessed portions are formed in the photoresist film 500 as illustrated in FIG. 9B. The photoresist film 502 having the patterns formed therein includes openings 503 corresponding to the island patterns 403. In this process, the patterns are formed in the effective chip segments 102a, and the ineffective chip segments 103a, 103b as illustrated in FIG. 1A. This stabilizes the processed dimensions, processed shapes and flatness over the entire surface of the semiconductor wafer 110. However, the mask pattern used for the effective chip segments 102a is different from the mask pattern used for the ineffective chip segments 103a, 103b. Specifically, the mask pattern 400 illustrated in FIG. 8A is used for the effective chip segments 102a, whereas the mask pattern 402 illustrated in FIG. 8B is used for the ineffective chip segments 103a, 103b, as described above.

The mask pattern 402 used for the ineffective chip segments 103a, 103b and illustrated in FIG. 8B includes the multiple island patterns 403, as described above. Each island pattern 403 corresponds to a recessed portion having an area of 10 μm² or smaller in terms of the projected area. In addition, the maximum width of each island pattern 403 is desirably equal to or smaller than the maximum width of patterns including the patterns 401 in the mask pattern 400 illustrated in FIG. 8A.

Moreover, a pattern density in the mask pattern 402 used for the ineffective chip segments 103a, 103b is desirably lower than a pattern density in the mask pattern 400 used for the effective chip segments 102a. The pattern density mentioned herein denotes a density of patterns corresponding to the openings in the resist pattern formed in the photoresist film.

Next, the inter-layer insulating film 114 and the stopper insulating film 113 are sequentially dry-etched by using the photoresist film 502 as a mask. Thereby, multiple recessed portions 604 being trenches for forming wirings are formed in the inter-layer insulating film 114 and the stopper insulating film 113, as illustrated in FIG. 9C.

Then, the photoresist film 502 is removed by asking, for example.

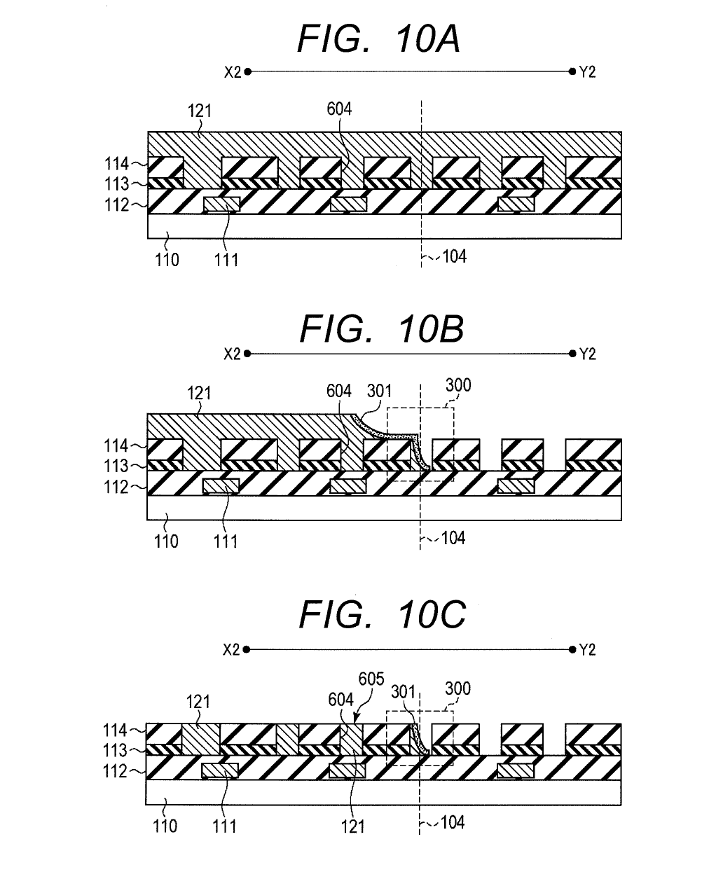

Thereafter, a barrier metal film (not illustrated) such as a Ti film or a TiN film is formed by sputtering, for example, on the inter-layer insulating film 114 having the multiple recessed portions 604 therein. Then, a seed film (not illustrated) made of a copper film is formed on the barrier metal film by sputtering, for example. Next, as illustrated in FIG. 10A, a copper film 121 as a conductive film is formed on the seed film by electroplating, for example, such that the multiple recessed portions 604 are filled with the copper film 121.

After that, as illustrated in FIG. 10B, the copper film 121 deposited as an unnecessary conductive film on the outer peripheral portion, the side surface, and the back surface of the semiconductor wafer 110 is removed while the copper film 121 is left on the region including the outer edge 104. Thus, on the principal surface of the semiconductor wafer 110, the copper film 121 is left on the region inside the outer edge 104, while the copper film 121 is removed from the region outside the outer edge 104. This removal uses, as a remover liquid, an aqueous solution of nitric acid, concentrated sulfuric acid, sulfuric acid/hydrogen peroxide mixture, or the like, for example, as described above. In addition, the removal method is not particularly limited as long as the method can remove the unnecessary copper film 121 from the outer peripheral portion, the side surface, and the back surface of the semiconductor wafer 110 by using a remover liquid.

In this process, also in the present embodiment, a section 300 where the copper film 121 is only partly removed and still partly remains is formed around the boundary of the region where the process of removing the unnecessary copper film 121 is performed, that is, around the outer edge 104. The surface of the copper film 121 in this section 300 where the copper film 121 partly remains is modified by the remover liquid used in the aforementioned removal. As a result, a modified layer 301 of the copper is formed on the surface of the copper film 121 in the section 300.

In the present embodiment, in the ineffective chip segments 103a, 103b, the resist pattern in the photoresist film 502 for forming the recessed portions 604 is formed by using the mask pattern 402 including the island patterns 403 illustrated in FIG. 8B. By use of the photoresist film 502 thus formed, the area proportion of the recessed portions each having a projected area of 10 μm² or smaller on the wafer is higher in the ineffective chip segments 103a, 103b than in the effective chip segments 102a, as described above. When the recessed portions 604 are thus formed by using the photoresist film 502 patterned corresponding to the area proportion of the recessed portions, the area of the copper film 121 remaining in the section 300 in the removal of the unnecessary copper film 121 can be made small. Thus, in the present embodiment, the area of the modified layer 301 formed is smaller than in the case of the reference mode (see FIG. 4B).

Subsequently, as illustrated in FIG. 10C, the copper film 121, the seed film and the barrier metal film on the inter-layer insulating film 114 are polished by using CMP. This process selectively removes part of the copper film 121, the seed film, and the barrier metal film on the inter-layer insulating film 114 outside the multiple recessed portions 604. Thus, a wiring layer 605 having the copper films 121 filled inside the recessed portions 604 is formed. In the present embodiment, the recessed portions 604 are formed by using the mask pattern 402 including the island patterns 403 illustrated in FIG. 8B, as described above. For this reason, in the present embodiment, steps are less likely to be generated in the section 300 where the copper film 121 partly remains, and therefore the slurry sticking is less likely to occur than in the case of the reference mode (see FIG. 4C).

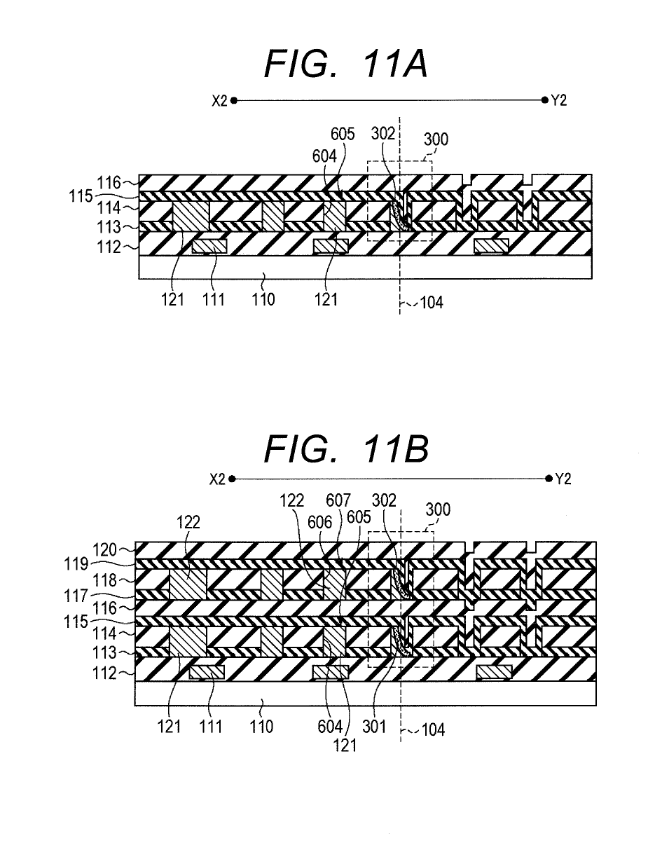

Subsequently, as illustrated in FIG. 11A, a barrier insulating film 115 and an inter-layer insulating film 116 are sequentially deposited on the inter-layer insulating film 114 having the wiring layer 605 embedded therein, as in the reference mode. Here, a high refractive index film having a higher refractive index than the inter-layer insulating film 114 can be used as the barrier insulating film 115. Specifically, when the inter-layer insulating film 114 is made of a silicon oxide film, the barrier insulating film 115 made of a silicon nitride film may be used.

As described above also in the present embodiment, the modified layer 301 is present on the surface of the copper film 121 in the section 300 where the copper film 121 partly remains. However, in the present embodiment, the area of the modified layer 301 formed is smaller than in the case of the reference mode (see FIG. 5A), which inhibits deterioration in the adhesion between barrier insulating film 115 on top of the modified layer 301, and its underlying layer. In addition, in the present embodiment, the slurry sticking is less likely to occur in the section 300 in the polishing by CMP, and accordingly the modified layer 301 is less likely to be an origin for delamination.

Thereafter, the wiring formation processes described by using FIGS. 9B to 11A are repeated. In this way, a multilayer wiring including multiple wiring layers is formed as illustrated in FIG. 11B. In an example illustrated in FIG. 11B, a stopper insulating film 117 and an inter-layer insulating film 118 are formed on an inter-layer insulating film 116, and a wiring layer 607 having copper films 122 filled in recessed portions 606 formed in the stopper insulating film 117 and the inter-layer insulating film 118 is formed. A modified layer 302 similar to the modified layer 301 is formed on the surface of the copper film 122 remaining in the section 300. Then, a barrier insulating film 119 and an inter-layer insulating film 120 are sequentially deposited on the inter-layer insulating film 118 having the wiring layer 607 embedded therein. In the present embodiment, the recessed portions 606 are also formed by using a mask pattern including island patterns as in the case of the recessed portions 604. Thus, the area of the modified layer 302 formed can also be made smaller than in the case of the reference mode.

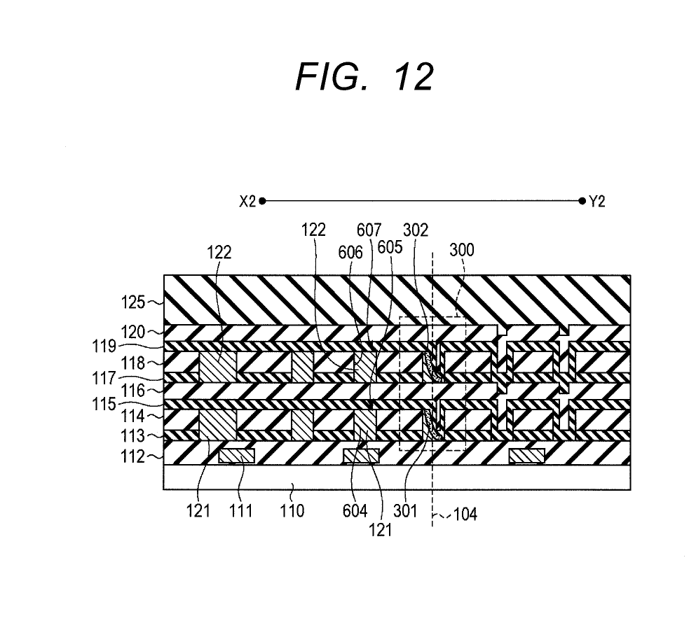

Next, as illustrated in FIG. 12, a passivation film 125 is formed on the inter-layer insulating film 120, as in the reference mode. In addition, in a process after the formation of the passivation film 125, the semiconductor wafer 110 having the multilayer wiring formed therein is thermally treated in an atmosphere containing a hydrogen gas, as in the reference mode. Thereafter, the semiconductor wafer 110 having the multilayer wiring formed therein is divided into multiple chips. Rectangular chips are obtained from the effective chip segments 102a in the effective region 106 and rectangular and non-rectangular chips are obtained from the ineffective chip segments 103a, 103b in the ineffective region 105.

In the present embodiment, since the areas of the aforementioned modified layers 301, 302 are small, the deterioration in the adhesion between the barrier insulating films 115, 119 and their underlying layers can be inhibited. In addition, the slurry sticking is less likely to occur in the section 300 in the polishing by CMP. For these reasons, the modified layers 301, 302 are less likely to be an origin for delamination. According to the present embodiment, therefore, delamination originating from any of the modified layers 301, 302 may be inhibited even though stress such as the film stress due to the passivation film 125 and the thermal stress due to the thermal treatment is applied to the semiconductor wafer 110 including the inter-layer insulating films and the like.

As described above, according to the present embodiment, it is possible to improve the yield by suppressing delamination around the boundary of a region where an unnecessary copper film is removed. Moreover, the suppression of the delamination can inhibit contamination by the copper due to the baring of the copper film.

### Second Embodiment

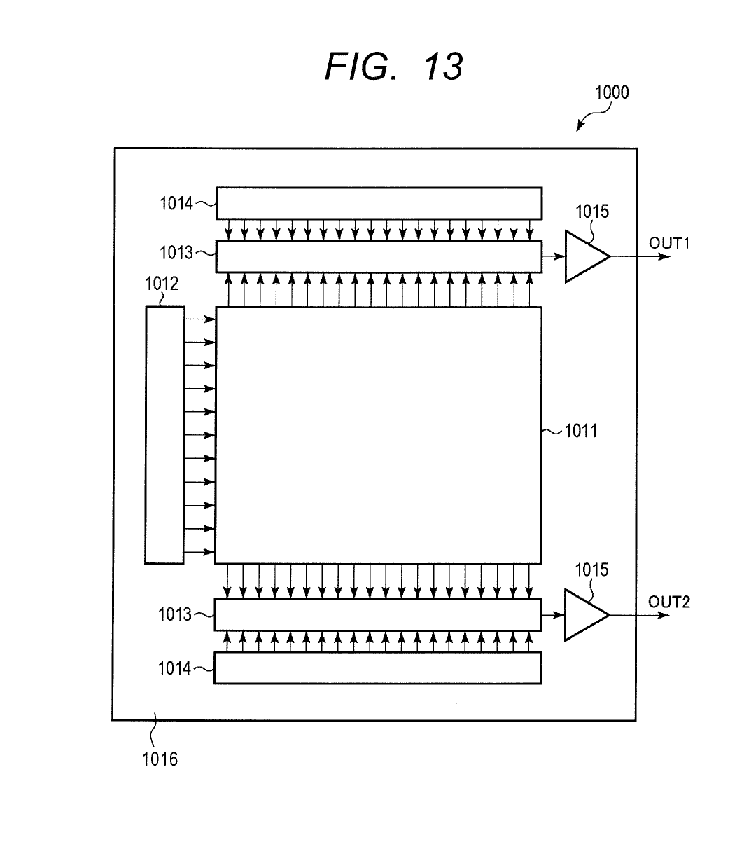

A semiconductor device according to a second embodiment of the present invention is described by using FIG. 13. FIG. 13 is a schematic plan view illustrating a configuration of the semiconductor device according to the present embodiment. Note that, constituent elements similar to those in the reference mode and the first embodiment will be assigned with the same reference numerals, and the explanation thereof will be omitted or simplified. In addition, the drawings used for the explanation of the reference mode will be referred to as needed.

In the present embodiment, a configuration of a solid-state image sensor will be described as an example of the semiconductor device of the present invention.

A solid-state image sensor 1000 according to the present embodiment corresponds to one segment (semiconductor device) 102 illustrated in FIG. 1A, and is a solid-state image sensor of a complementary metal oxide semiconductor (CMOS) type, for example. As illustrated in FIG. 13, the solid-state image sensor 1000 includes a pixel unit 1011, a vertical scan circuit 1012, two reader circuits 1013, two horizontal scan circuits 1014, and two output amplifiers 1015. Note that a region other than the pixel unit 1011 is referred to as a peripheral circuit unit 1016.

The pixel unit 1011 includes multiple pixels arranged in a two-dimensional array. Each pixel at least includes a photoelectric conversion element, and may additionally include a transistor and other elements for reading. Each of the reader circuits 1013 includes, for example, a column amplifier, a correlated double sampling (CDS) circuit, an adder circuit and the like. The reader circuit 1013 performs amplification, addition and the like on signals read through vertical signal lines from the pixels in a row selected by the vertical scan circuit 1012. The column amplifier, the CDS circuit, the adder circuit and the like are provided for each pixel column or each set of two or more pixel columns, for example. Each of the horizontal scan circuits 1014 generates signals for reading the signals of the corresponding reader circuit 1013 in a certain order. Each of the output amplifiers 1015 amplifies and outputs the signals of the column selected by the corresponding horizontal scan circuit 1014. In order to form two output paths, one set of the reader circuit 1013, the horizontal scan circuit 1014, and the output amplifier 1015 is arranged above the pixel unit 1011, and the other one set thereof is arranged below the pixel unit 1011. However, three or more output paths may be provided.

In order to form wiring layers in the foregoing solid-state image sensors 1000, the mask pattern 402 used for the ineffective chip segments 103a, 103b illustrated in FIG. 1A is designed by employing the island patterns 403 at least for patterns for forming a wiring pattern in the peripheral circuit units 1016. In addition, the area of a recessed portion corresponding to each island pattern 403 is set to 10 μm² or smaller in terms of the projected area.

In the ineffective chip segments 103a, 103b, a mask pattern for forming a wiring pattern of the pixel units 1011 may be the same as a mask pattern for forming the effective solid-state image sensor 1000, or may be a mask pattern including the island patterns 403 described above. This is because the pixel unit 1011 is generally designed to have a narrower wiring width than that of the peripheral circuit unit 1016, and therefore is less likely to have delamination. With the configuration described above, it is possible to stabilize the processed dimensions, processed shapes and flatness over the entire surface of the wafer while suppressing delamination.

The configuration described above is just one non-limiting configuration example of the solid-state image sensor. For example, the solid-state image sensor 1000 may also be of a charged coupled device (CCD) type.

### Modified Embodiment

The present invention is not limited to the foregoing embodiments, but can be modified variously.

For example, the foregoing embodiments are described by taking, as an example, the case where the copper film is used as the conductive film filled into the recessed portions, but the conductive film is not limited to the copper film. The conductive film filled into the recessed portions may be any of films made of various metal materials that can form a wiring layer, besides a copper film or a copper alloy film containing copper as a main ingredient.

In addition, the foregoing embodiments are described by taking, as an example, the case where a single damascene process is employed as the damascene process for forming the wiring layer. Instead of this, the wiring layer and conductor plugs may be formed together and integrally by a dual damascene process, for example.

Moreover, the foregoing second embodiment is described by taking the solid-state image sensor as an example of the semiconductor device to which the present invention is applicable. Instead, the present invention is also applicable to other semiconductor devices such as memories.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-009238, filed on Jan. 21, 2015, which is hereby incorporated by reference herein in its entirety.

What is claimed is:

1. A method of manufacturing a semiconductor device, the method comprising the steps of:
forming a plurality of recessed portions in an insulating film formed above a wafer including a first region and a second region outside the first region such that the recessed portions are formed above both the first region and the second region;
forming a conductive film on the insulating film such that the plurality of recessed portions are filled with the conductive film;
removing the conductive film above the second region while leaving the conductive film above the first region; and
removing part of the conductive film remaining above the first region outside the plurality of recessed portions,
wherein an area proportion of the recessed portions each having a projected area of 10 μm² or smaller on the wafer among the plurality of recessed portions is higher in the second region than in the first region.

2. The method of manufacturing a semiconductor device according to claim 1, wherein an area proportion of the recessed portions each having a projected area over 10 μm² on the wafer among the plurality of recessed portions is higher in the first region than in the second region.

3. The method of manufacturing a semiconductor device according to claim 1, wherein among the plurality of recessed portions, the recessed portions in the second region are only recessed portions each having the projected area of 10 μm² or smaller on the wafer.

4. The method of manufacturing a semiconductor device according to claim 1, wherein a maximum width of the recessed portions in the second region is equal to or smaller than a maximum width of the recessed portions in the first region.

5. The method of manufacturing a semiconductor device according to claim 1, wherein an area proportion of the recessed portions each having the projected area of 10 μm² or smaller on the wafer among the plurality of recessed portions is equal to or more than 35%, but less than 100% in the second region.

6. The method of manufacturing a semiconductor device according to claim 1, wherein each of the recessed portions having a projected area of 10 μm² or smaller on the wafer in the second region is formed such that a dimension of the recessed portion in a first direction along the wafer is 1 to 1000 times as large as a dimension of the recessed portion in a second direction along the wafer and orthogonal to the first direction.

7. The method of manufacturing a semiconductor device according to claim 1, wherein a plurality of photoelectric conversion elements are formed on the wafer.

8. The method of manufacturing a semiconductor device according to claim 1, further comprising the step of
dividing the wafer to obtain a plurality of chips,
wherein a rectangular chip is obtained from the first region, and a non-rectangular chip is obtained from the second region.
